(19) United States
(12) Patent Application Publication
(10) Pub. No.: US 2024/0030877 A1
(43) Pub. Date: Jan. 25, 2024

(54) POWER AMPLIFIER CIRCUIT

(71) Applicant: Murata Manufacturing Co., Ltd., Kyoto (JP)

(72) Inventor: Takashi SOGA, Kyoto (JP)

(21) Appl. No.: 18/356,565

(22) Filed: Jul. 21, 2023

(30) Foreign Application Priority Data
Jul. 22, 2022 (JP) 2022-117247

(51) Int. Cl. H03F 3/21; H03F 1/30; H03F 1/02

(52) U.S. Cl. CPC H03F 3/21; H03F 1/302; H03F 1/0216; H03F 2200/451

(57) ABSTRACT

A power amplifier circuit includes a first transistor having a base supplied with a bias current, configured to amplify an input signal and to output a first current, a second transistor having an emitter connected to the base of the first transistor, configured to supply the bias current from the emitter to the base of the first transistor, a third transistor connected to a base of the second transistor, a comparison voltage generation circuit, configured to generate a comparison voltage based on a second current flowing through the third transistor, and a comparison circuit connected to the base of the second transistor, to which the comparison voltage and a reference voltage are supplied, configured to decrease a third current supplied to the base of the second transistor as the second current increases based on the comparison voltage and the reference voltage.

### CROSS REFERENCE TO RELATED APPLICATION

This application claims priority from Japanese Patent Application No. 2022-117247 filed on Jul. 22, 2022. The content of this application is incorporated herein by reference in its entirety.

### BACKGROUND OF THE DISCLOSURE

### 1. Field of the Disclosure

The present disclosure relates to a power amplifier circuit.

### 2. Description of the Related Art

There is a trend to increase the output of an amplifier by increasing a power supply voltage supplied to the amplifier or increasing a current flowing through an amplifier element. However, as the output is increased, the amplifier element is easily broken by a voltage or a current. Therefore, it is necessary to prevent the breakdown of the amplifier element while enabling high output. International Publication No. 2020/080332 discloses a configuration in which, in order to prevent the breakdown of the amplifier element, an overcurrent state of the amplifier element is detected based on a voltage drop of a resistor arranged in a power amplifier circuit, and when a detected potential exceeds a reference threshold value, an operation of a current mirror circuit for bias current input is interrupted.

There are methods for controlling the output power of the power amplifier circuit, such as a method for controlling the input power while keeping a gain of the power amplifier circuit constant and a method for controlling the gain of the power amplifier circuit while keeping the input power constant. When the method for controlling the input power is employed to control the output power, the amplifier element may operate in a saturation state. When high input is applied to the amplifier element operating in a saturation state for increasing the output, the amplifier element is particularly likely to be broken. Therefore, when the amplifier element operates in the saturation state, it is necessary to suppress the power inputted to the amplifier. In this regard, it is conceivable to use the configuration described in International Publication No. 2020/080332, but the configuration described in International Publication No. 2020/080332 has many circuit elements and the configuration becomes complicated.

### BRIEF SUMMARY OF THE DISCLOSURE

The present disclosure has been made in view of such circumstances, and a possible benefit of the present disclosure is to provide a power amplifier circuit capable of preventing the breakdown of an amplifier element with a simple circuit configuration when input power increases.

According to an aspect of the present disclosure, there is provided a power amplifier circuit including a first transistor having a base or gate to which a bias current or voltage is supplied, and configured to amplify an input signal and to output a first current, a second transistor having an emitter or a source connected to the base or gate of the first transistor, and configured to supply the bias current or voltage (bias voltage) from the emitter or source to the base or gate of the first transistor, a comparison voltage generation circuit including a third transistor connected to a base or gate of the second transistor, and configured to generate a comparison voltage based on a second current flowing through the third transistor, and a comparison circuit connected to the base or gate of the second transistor, supplied with the comparison voltage and a reference voltage, and configured to decrease a third current supplied to the base or gate of the second transistor as the second current increases based on the comparison voltage and the reference voltage.

According to another aspect of the present disclosure, there is provided a power amplifier circuit including a first transistor having a base or gate to which a first bias current or voltage is supplied, and configured to amplify a first signal and to output a first current, a second transistor having an emitter or a source connected to the base or gate of the first transistor, and configured to supply the first bias current or voltage from the emitter or source to the base or gate of the first transistor, a comparison voltage generation circuit including a third transistor connected to a base or gate of the second transistor, and configured to generate a comparison voltage based on a second current flowing through the third transistor, a fourth transistor having a base or gate to which a second bias current or voltage is supplied and a collector or drain is connected to the base or gate of the first transistor, and configured to amplify an input signal and to output the first signal, a fifth transistor having an emitter or a source connected to a base or gate of the third transistor, and configured to supply the second bias current or voltage from the emitter or source to the base or gate of the third transistor, and a comparison circuit connected to the base or gate of the second transistor and connected to a base or gate of the fifth transistor, supplied with the comparison voltage and a reference voltage, and configured to decrease a third current supplied to the base or gate of the fifth transistor based on the comparison voltage and the reference voltage.

According to the present disclosure, with a simple circuit configuration, it is possible to provide a power amplifier circuit capable of preventing the breakdown of an amplifier element when input power becomes large.

### BRIEF DESCRIPTION OF THE SEVERAL VIEWS OF THE DRAWINGS

FIG. 1 is a circuit diagram of a power amplifier circuit according to a first embodiment;

FIG. 2 is a circuit diagram of a power amplifier circuit according to a second embodiment;

FIG. 3 is a diagram illustrating an operation of the power amplifier circuit according to the second embodiment;

FIG. 4A and FIG. 4B are diagrams illustrating an operation of the power amplifier circuit according to the second embodiment;

FIG. 5A and FIG. 5B are diagrams illustrating an operation of the power amplifier circuit according to the second embodiment;

FIG. 6 is a diagram illustrating another example of a comparison voltage generation circuit;

FIG. 7 is a diagram illustrating still another example of a comparison voltage generation circuit;

FIG. 8 is a detailed circuit diagram of the power amplifier circuit according to the second embodiment; and

FIG. 9 is another detailed circuit diagram of the power amplifier circuit according to the second embodiment.

### DETAILED DESCRIPTION OF THE DISCLOSURE

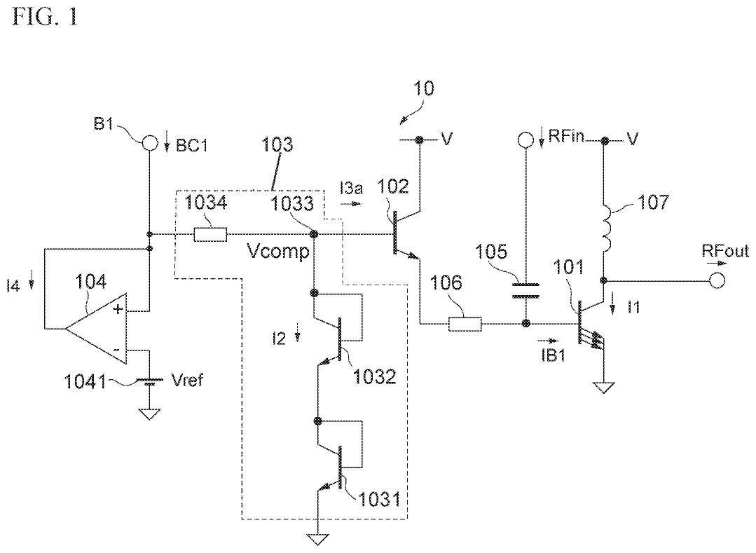

A first embodiment will be described. FIG. 1 is a schematic circuit diagram of a power amplifier circuit according to a first embodiment. A power amplifier circuit includes transistors 101 and 102, a comparison voltage generation circuit 103, a comparison circuit 104, a capacitor 105, a resistance element 106, and an inductor 107. The transistor 101 amplifies an input signal RFin and outputs an output signal RFout from a collector. The input signal RFin includes a current and a voltage. The output signal RFout includes a current.

In the transistor 101 (first transistor), a base is connected to the input side, the collector is connected to the output side, and an emitter is connected to a ground. The input signal RFin is inputted to the base. A bias current or voltage is supplied to the base of the transistor 101 from a transistor 102 described later. Here, an example is illustrated in which a bias current IB1 is supplied to the base of the transistor 101. A power supply voltage V is supplied to the collector of the transistor 101. A current I1 (first current) flows through the collector of the transistor 101.

The capacitor 105 for interrupting a direct current signal of the input signal RFin is connected to the base of the transistor 101. The collector of the transistor 101 is connected with an inductor 107 that suppresses an alternating current signal from flowing into the power supply.

An emitter of the transistor 102 (second transistor) is connected to the base of the transistor 101, a collector thereof is connected to the power supply, and a base thereof is connected to a bias control terminal B1 through the comparison voltage generation circuit 103 described later. The transistor 102 supplies a bias current or voltage to the transistor 101 in accordance with a bias control signal BC1 supplied from the bias control terminal B1. Here, an example is illustrated in which a current I3a (third current) is supplied to the base of the transistor 102 as a bias current. In addition, a resistance element 106 is provided between the base of the transistor 101 and the emitter of the transistor 102.

The transistors 101 and 102 are constituted by a bipolar transistor such as a heterojunction bipolar transistor (HBT). Note that the transistors 101 and 102 may be constituted by a field effect transistor such as a metal-oxide-semiconductor field-effect transistor (MOSFET) instead of the HBT. In this case, a collector, a base, and an emitter described below may be read as a drain, a gate, and a source, respectively. The same applies to the transistors in the following embodiments described below.

The comparison voltage generation circuit 103 is provided between the base of the transistor 102 and the bias control terminal B1. The comparison voltage generation circuit 103 includes transistors 1031 (third transistor) and 1032, a connection point 1033, and a resistance element 1034.

The transistors 1031 and 1032 are diode-connected transistors. An emitter of the transistor 1031 is connected to the ground. A collector of the transistor 1031 is connected to an emitter of transistor 1032. A collector of the transistor 1032 is connected to the base of transistor 102 through the connection point 1033. The collector of the transistor 1032 is connected to the resistance element 1034 through the connection point 1033.

The transistors 1031 and 1032 are transistors, for example, formed on the same semiconductor chip as the transistor 101. In this case, a temperature state of the transistor 101 is equivalent to temperature states of the transistors 1031 and 1032. In addition, the transistors 101, 1031 and 1032 may be formed on a semiconductor chip so that temperature characteristics of the transistor 101 and temperature characteristics of the transistors 1031 and 1032 are common.

The transistors 1031 and 1032 generate a comparison voltage Vcomp at the connection point 1033 based on a current I2 (second current) flowing in common to the respective transistors 1031 and 1032. The comparison voltage at the connection point 1033 is 2 Vbe, when Vbe is an operating voltage of each of the transistors 1031 and 1032.

The comparison circuit 104 is connected to the bias control terminal B1 and the comparison voltage generation circuit 103. The comparison circuit 104 is connected to the base of the transistor 102 through the comparison voltage generation circuit 103. A reference voltage Vref is supplied from a reference voltage source 1041 that generates the reference voltage Vref to the comparison circuit 104. The comparison circuit 104 extracts a current I4 (fourth current) from a bias control terminal B1 side based on the comparison voltage Vcomp and the reference voltage Vref. The comparison circuit 104 is represented as, for example, a differential amplifier having a non-inverted input terminal and an inverted input terminal. In FIG. 1, the comparison circuit 104 has the non-inverted input terminal connected to the bias control terminal B1 and the comparison voltage generation circuit 103, and the inverted input terminal connected to the reference voltage source 1041. In addition, the output of the comparison circuit 104 is connected to the bias control terminal B1 and the comparison voltage generation circuit 103.

The comparison circuit 104 generates the current I4 based on the comparison voltage Vcomp and the reference voltage Vref so as to decrease the current I3a as the current I2 increases.

An operation of the power amplifier circuit 10 will be described.

In the power amplifier circuit 10, the current I1 flows through the collector of the transistor 101 in accordance with the input signal RFin and the bias current IB1. The transistor 101 generates heat when the power amplification is performed, and an amount of the heat generation increases in accordance with an increase in the current I1. That is, when the output power of the transistor 101 increases, the amount of the heat generation of the transistor 101 increases.

When the transistor 101 generates heat, a temperature of the transistor 101 increases. In addition, as the temperature of the transistor 101 increases, for example, the temperatures of the transistors 1031 and 1032 provided on the same chip and arranged thermally close to each other also increase.

As the temperatures of the transistors 1031 and 1032 increase, operating points of the transistors 1031 and 1032 change. To be specific, the operating points of the transistors 1031 and 1032 change so that a threshold voltage for the current I2 to flow decreases. A decrease in the threshold voltage leads to an increase in the current I2 flowing through the transistors 1031 and 1032 at a certain voltage value. The transistors 1031 and 1032 also cause a decrease in the comparison voltage Vcomp generated at the connection point 1033.

When the comparison voltage Vcomp decreases, the difference between the voltage at the non-inverted input terminal and the reference voltage Vref at the inverted input terminal increases. The comparison circuit 104 draws the current I4 from the bias control terminal B1 based on this differential voltage.

As a result, the current I3a supplied to the base of the transistor 102 decreases in accordance with the current I4. When the current I3a decreases, the bias current IB1 supplied by the transistor 102 to the transistor 101 decreases. By decreasing the bias current IB1, the current I1 decreases. Accordingly, an increase in the current I1 is suppressed. Since the increase in the current I1 is suppressed, the transistor 101 can be prevented from being broken due to an overcurrent.

A second embodiment will be described. In the second embodiment, the description of the matters common to the first embodiment will be omitted, and only different points will be described. In particular, similar functions and effects obtained by similar configurations will not be mentioned in each embodiment.

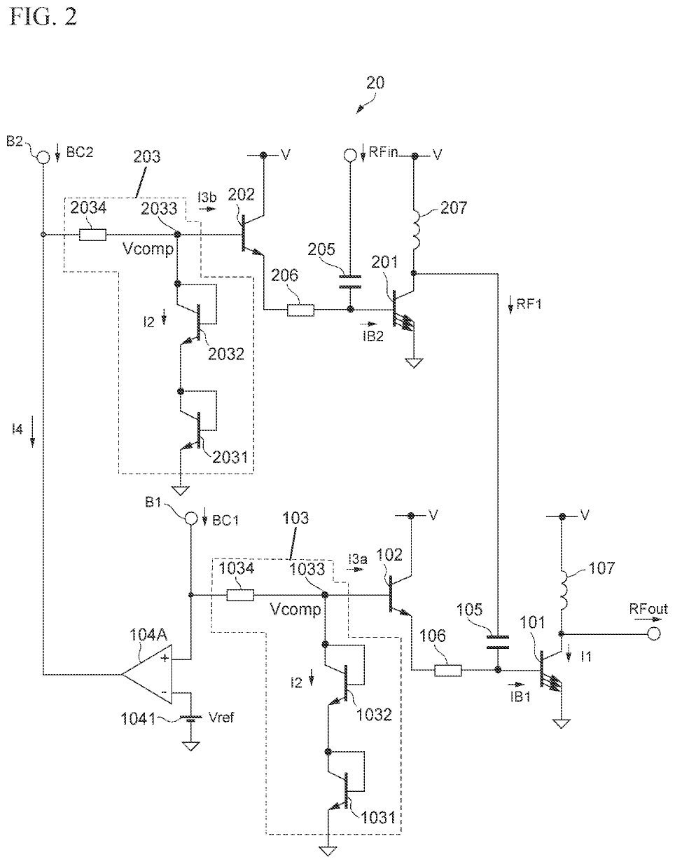

FIG. 2 is a schematic circuit diagram of a power amplifier circuit 20 according to the second embodiment. The power amplifier circuit 20 includes transistors 101 and 102, the comparison voltage generation circuit 103, a comparison circuit 104A, the capacitor 105, the resistance element 106, the inductor 107, transistors 201 and 202, a comparison voltage generation circuit 203, a capacitor 205, a resistance element 206, and an inductor 207.

In the power amplifier circuit 20, a base of the transistor 101 is connected to a collector of the transistor 201 through the capacitor 105. In the power amplifier circuit 20, an input signal RFin is inputted to the transistor 201, and the transistor 201 amplifies the input signal RFin and outputs a signal RF1 from the collector. The signal RF1 is inputted to the transistor 101, and the transistor 101 amplifies the signal RF1 and outputs an output signal RFout.

In addition, the power amplifier circuit 20 is different from the power amplifier circuit 10 according to the first embodiment in that the comparison circuit 104A is connected to the transistor 202 to be described later.

A base of the transistor 201 (fourth transistor) is connected to an input terminal, the collector thereof is connected to an output terminal and the transistor 101, and an emitter thereof is connected to the ground. A bias current or voltage is supplied to the base of the transistor 201 from the transistor 202 described later. Here, an example is described in which a bias current IB2 is supplied to the base of the transistor 201. A power supply voltage V is supplied to the collector of the transistor 201.

The capacitor 205 for cutting a direct current signal of the input signal RFin is connected to the base of the transistor 201. The collector of the transistor 201 is connected with an inductor 207 that suppresses an alternating current signal from flowing into the power supply.

An emitter of the transistor 202 (fifth transistor) is connected to the base of the transistor 201, a collector thereof is connected to the power supply, and a base thereof is connected to a bias control terminal B2 through the comparison voltage generation circuit 203 described later. The transistor 202 supplies a bias current or voltage to the transistor 201 in accordance with a bias control signal BC2 supplied from the bias control terminal B2. Here, an example is illustrated in which a current I3b (third current) is supplied to the base of the transistor 202 as a bias current. In addition, a resistance element 206 is provided between the base of the transistor 201 and the emitter of the transistor 202.

The comparison voltage generation circuit 203 is provided between the base of the transistor 202 and the bias control terminal B2. The comparison voltage generation circuit 203 includes transistors 2031 and 2032, a connection point 2033, and a resistance element 2034. The comparison voltage generation circuit 203 has functions similar to those of the comparison voltage generation circuit 103. The transistors 2031 and 2032, the connection point 2033, and the resistance element 2034 are elements having connection relations and properties similar to those of transistors 1031 and 1032, the connection point 1033, and the resistance element 1034.

The comparison circuit 104A is connected to the bias control terminal B1, the comparison voltage generation circuit 103, the bias control terminal B2, and the comparison voltage generation circuit 203. The comparison circuit 104A is connected to the base of the transistor 202 through the comparison voltage generation circuit 203. A reference voltage Vref is supplied to the comparison circuit 104A from the reference voltage source 1041 that generates the reference voltage Vref. The comparison circuit 104A extracts the current I4 (fourth current) from a bias control terminal B2 side based on a comparison voltage Vcomp and the reference voltage Vref. The comparison circuit 104 is represented as, for example, a differential amplifier having a non-inverted input terminal and an inverted input terminal. In FIG. 2, the comparison circuit 104A has the non-inverted input terminal connected to the bias control terminal B1 and the comparison voltage generation circuit 103, and the inverted input terminal connected to the reference voltage source 1041. In addition, the output of the comparison circuit 104A is connected to the bias control terminal B2 and the comparison voltage generation circuit 203.

Based on the comparison voltage Vcomp generated by the comparison voltage generation circuit 103 and the reference voltage Vref, the comparison circuit 104A generates the current I4 such that the current I3b decreases with decrease in the comparison voltage Vcomp.

An operation of the power amplifier circuit 20 will be described.

The power amplifier circuit 20 is similar to the power amplifier circuit 10 in that the current I1 flows through a collector of the transistor 101 in accordance with the bias current IB1 and the output signal RF1 in accordance with the input signal RFin, and the amount of heat generation of the transistor 101 increases. In addition, a temperature of the transistor 101 increases and operating points of the transistors 1031 and 1032 change as in the above case. This results in an increase in the current I2 flowing through the transistors 1031 and 1032 at a certain voltage value or decrease in the comparison voltage Vcomp generated at the connection point 1033 by the transistors 1031 and 1032.

When the comparison voltage Vcomp decreases, the difference between a voltage at the non-inverted input terminal of the comparison circuit 104A and the reference voltage Vref at the inverted input terminal increases. The comparison circuit 104A draws the current I4 from the bias control terminal B2 based on the differential voltage.

As a result, the current I3b supplied to the base of the transistor 202 decreases in accordance with the current I4. When the current I3b decreases, the bias current IB2 supplied by the transistor 202 to the transistor 201 decreases. As the bias current IB2 decreases, the power of the signal RF1 outputted by the transistor 201 decreases. Since the power of the signal RF1 inputted to the transistor 101 decreases, an increase in the current I1 is suppressed. Since the increase in the current I1 is suppressed, the transistor 101 can be prevented from being broken due to an overcurrent.

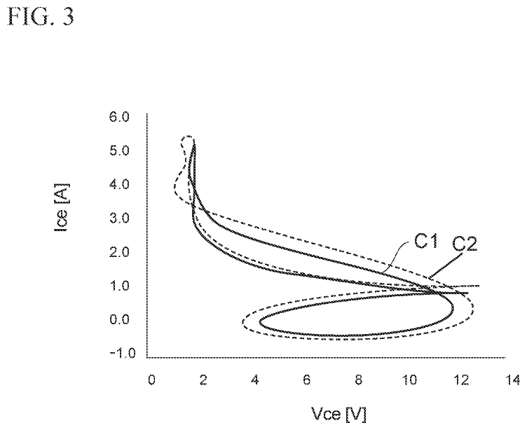

Suppression of output power in the power amplifier circuit 20 will be described with reference to FIG. 3 to FIGS. 5A and 5B. FIG. 3 is a graph plotting a relationship between a collector-emitter voltage Vce and a collector-emitter current Ice (current I1) of the transistor 101 when the power of a signal inputted to the transistor 201 is 10 dBm. The operation of the power amplifier circuit 20 is represented as a curve C1 indicated by the solid line. In addition, as a reference example, an operation in a power amplifier circuit not including the comparison voltage generation circuit 103 and the comparison circuit 104 is represented as a curve C2 indicated by the broken line.

Of particular note in FIG. 3 is the difference between the curve C1 and the curve C2 in the range where the collector-emitter voltage Vce is approximately 3 V to 10 V and the collector-emitter current Ice is 1.0 A to 3.0 A. The above range is an operating range in which loss (product of the collector-emitter voltage Vce and the collector-emitter current Ice) in the transistor 101 is likely to be large. In this range, the curve C1 is closer to a side of the origin than the curve C2, which indicates that the loss in the transistor 101 is suppressed. The loss in the transistor 101 is, in other words, the heat generation in the transistor 101, which indicates that the power amplifier circuit 20 can suppress the heat generation of the transistor 101. The suppression of the heat generation of the transistor 101 occurs as a result of the comparison circuit 104A decreasing the bias current supplied to the transistor 201.

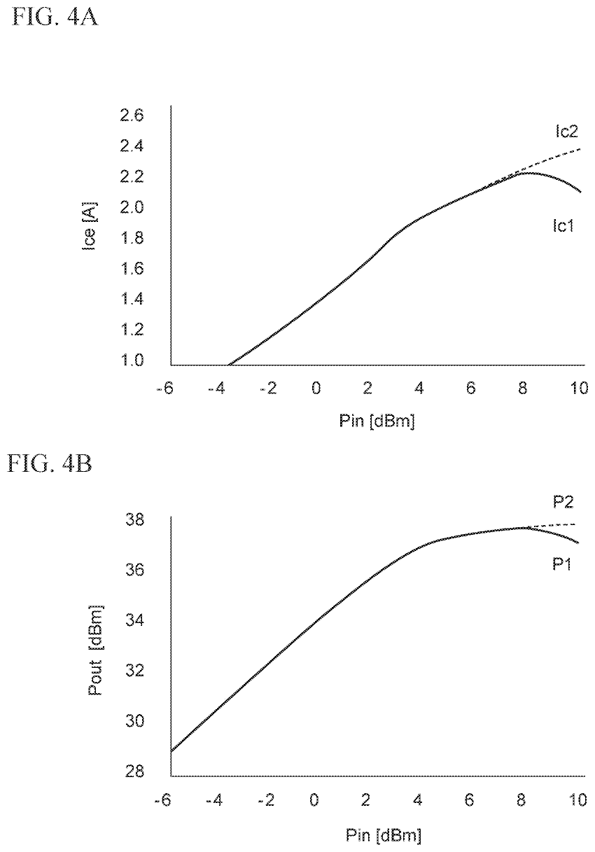

Next, the collector-emitter current Ice [A] of the transistor 101 and the output power Pout [dBm] from the transistor 101 when power Pin [dBm] of a signal inputted to the power amplifier circuit is changed will be described with reference to FIG. 4A and FIG. 4B.

In FIG. 4A, a current Ic1 which is the collector-emitter current Ice of the power amplifier circuit 20 is indicated by the solid line, and a current Ic2 which is the collector-emitter current Ice in the power amplifier circuit of the reference example is indicated by the broken line.

In FIG. 4B, the output power P1 from the transistor 101 of the power amplifier circuit 20 is indicated by the solid line, and the output power P2 from an output stage transistor in the power amplifier circuit of the reference example is indicated by the broken line.

As illustrated in FIG. 4A, in the power amplifier circuit 20, when input power increases, the current Ic1 flowing through the transistor 101 is suppressed as indicated. In particular, in a region of high input power where power Pin of an input signal is from 8 dBm to 10 dBm, the current Ic1 is smaller than the current Ic2.

As illustrated in FIG. 4B, as a result of the suppression of the current flowing through the transistor 101, the output power P1 is suppressed. In particular, in the region of high input power where power Pin of the input signal is from 8 dBm to 10 dBm, the output power P1 is smaller than the output power P2.

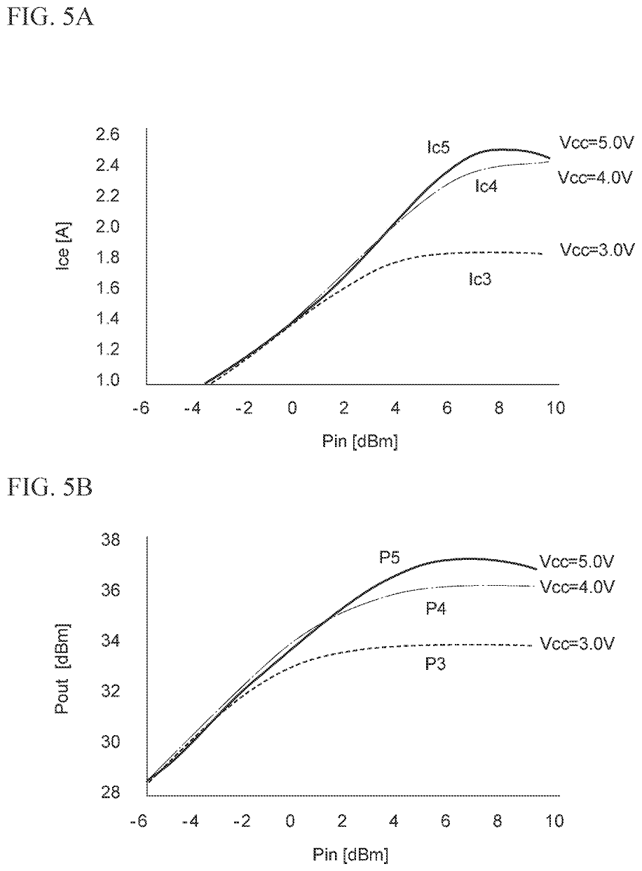

FIG. 5A and FIG. 5B are graphs illustrating changes of collector-emitter currents Ic3, Ic4, and Ic5 of the transistors 101, and output powers P3, P4, and P5 [dBm] with respect to the power Pin [dBm] of the input signal in the power amplifier circuit 20 when the power supply voltage V (Vcc) is set to Vcc=3.0, 4.0, and 5.0, respectively. As illustrated in FIGS. 5A and 5B, particularly when the power supply voltage has a value (for example, Vcc=5.0 V) at which the transistor 101 outputs high output, the collector-emitter current is suppressed, and as a result, the output power P5 is suppressed. On the other hand, in a case of low output power (for example, Vcc=3.0 V or 4.0 V), the collector-emitter currents Ic3 and Ic4 are not suppressed, and as a result, the output powers P3 and P4 are also not suppressed, and sufficient power amplification is performed. As described above, the power amplifier circuit 20 suppresses excessive input to the transistor 101 in a case of high output, and thus can suppress the breakdown of the transistor 101 while securing output in a case of low output or medium output.

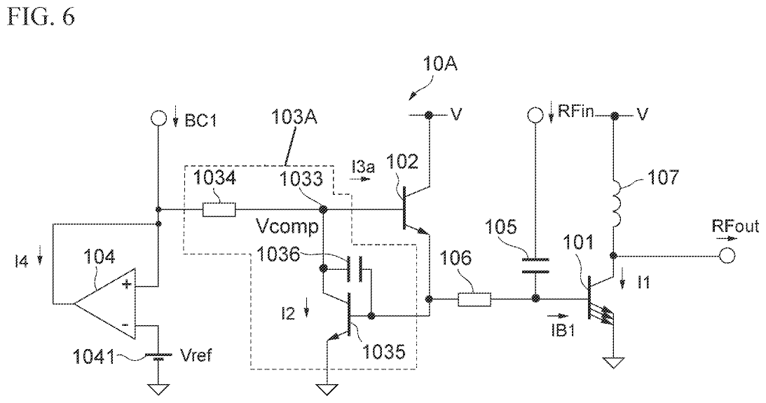

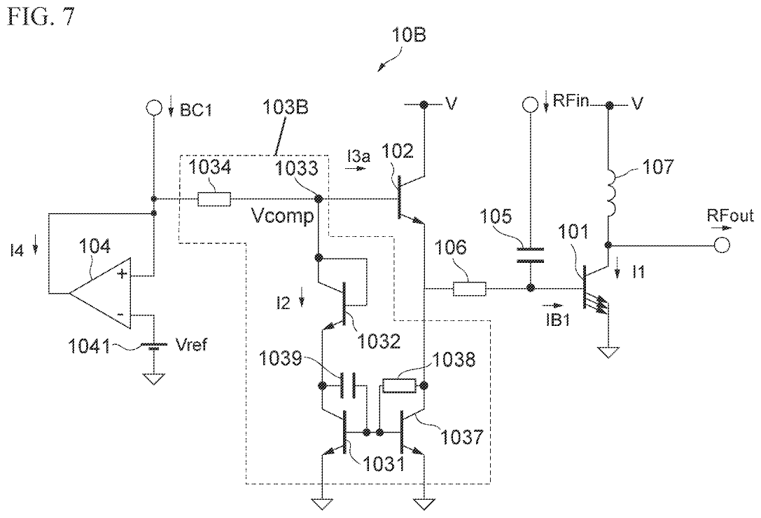

An example of another configuration of the comparison voltage generation circuit 103 in the power amplifier circuit 10 or the power amplifier circuit 20 will be described with reference to FIGS. 6 and 7. FIG. 6 illustrates a circuit diagram of a power amplifier circuit 10A in which the configuration of the comparison voltage generation circuit 103 is changed in the power amplifier circuit 10. A comparison voltage generation circuit 103A includes a transistor 1035 (third transistor) instead of the transistors 1031 and 1032. The comparison voltage generation circuit 103A can also generate the comparison voltage Vcomp at the connection point 1033, and the control can be performed by the comparison circuit 104.

FIG. 7 illustrates a circuit diagram of a power amplifier circuit 10B in which the configuration of the comparison voltage generation circuit 103 is changed in the power amplifier circuit 10. A comparison voltage generation circuit 103B includes a transistor 1037, a resistance element 1038, and a capacitor 1039 in addition to the transistors 1031 and 1032. The comparison voltage generation circuit 103B can also generate the comparison voltage Vcomp at the connection point 1033, and the control can be performed by the comparison circuit 104. The comparison voltage generation circuits 103A and 103B illustrated in FIGS. 6 and 7 can be similarly applied to the power amplifier circuit 20.

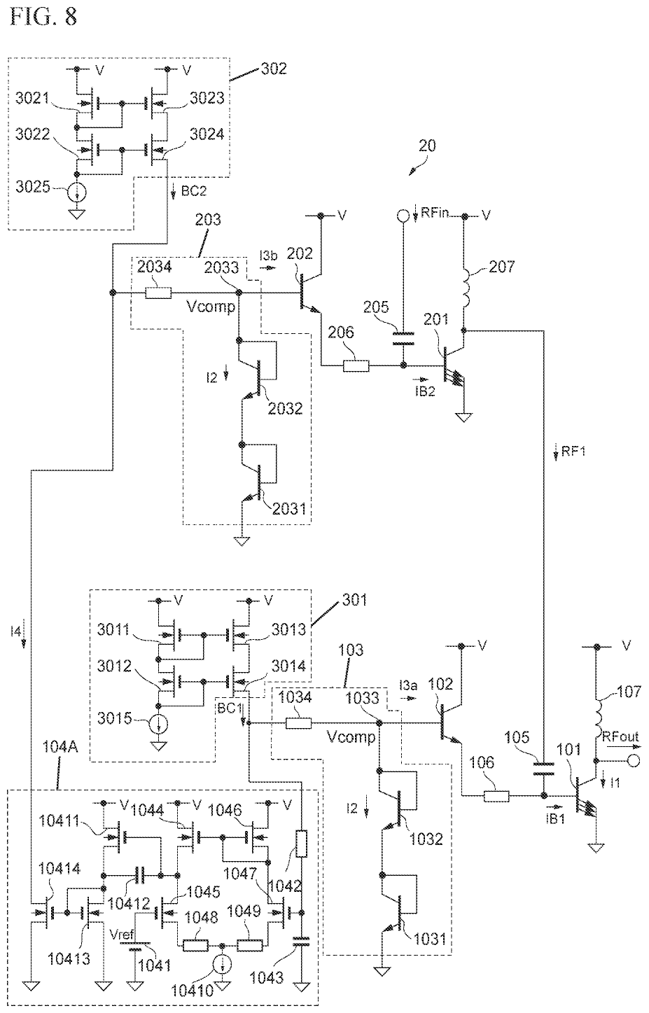

A detailed circuit diagram of the power amplifier circuit 20 will be described with reference to FIG. 8. As illustrated in FIG. 8, the power amplifier circuit 20 includes a bias control circuit 301 and a bias control circuit 302. The bias control circuit 301 includes transistors 3011, 3012, 3013, and 3014 and a current source 3015. In the bias control circuit 301, a pair of the transistors 3011 and 3013 and a pair of the transistors 3012 and 3014 are current mirror connected. The bias control circuit 301 supplies the bias control signal BC1 to the transistor 102 in accordance with a current from the current source 3015. The bias control circuit 302 includes transistors 3021, 3022, 3023, and 3024 and a current source 3025. The bias control circuit 302 supplies the bias control signal BC2 to the transistor 202 in accordance with a current from the current source 3025.

In addition to the reference voltage source 1041, the comparison circuit 104A includes a resistance element 1042, a capacitor 1043, transistors 1044, 1045, 1046, and 1047, resistance elements 1048 and 1049, a current source 10410, a transistor 10411, a capacitor 10412, and transistors 10413 and 10414.

In the comparison circuit 104A, a voltage corresponding to a difference between a voltage determined by the transistors 1045 and 1044 connected to the reference voltage source 1041 and a voltage determined by the transistors 1046 and 1047, and the resistance element 1049 in accordance with the comparison voltage Vcomp is supplied to a gate of the transistor 10414. The transistor 10414 operates to supply more voltage to the gate and to draw more current I4 as the difference between the reference voltage Vref and the comparison voltage Vcomp becomes larger.

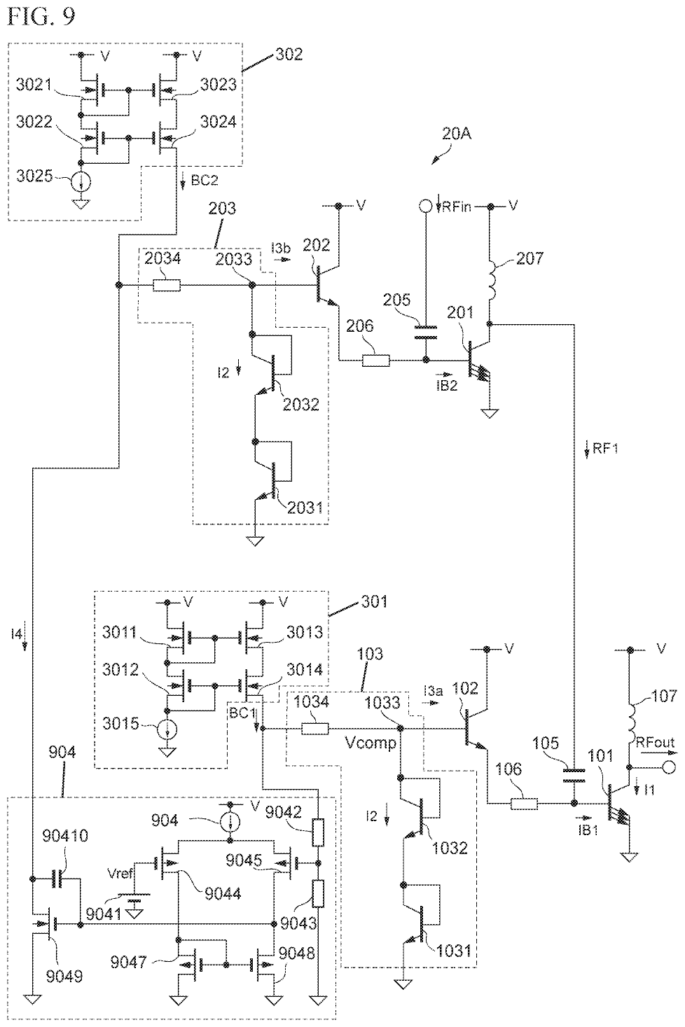

A detailed circuit diagram of a power amplifier circuit 20A, which is another example of the power amplifier circuit 20, will be described with reference to FIG. 9. As illustrated in FIG. 9, the power amplifier circuit 20A includes a comparison circuit 904 instead of the comparison circuit 104A. The comparison circuit 904 includes a reference voltage source 9041, resistance elements 9042 and 9043, transistors 9044 and 9045, a current source 9046, transistors 9047, 9048 and 9049, and a capacitor 90410. In the comparison circuit 904, a voltage corresponding to a difference between a voltage determined by the transistor 9044 connected to the reference voltage source 9041 and the transistor 9047 and a voltage determined by the transistors 9045 and 9048 in accordance with the comparison voltage Vcomp is supplied to a gate of the transistor 9049. The transistor 9049 operates to supply more voltage to the gate and to draw more current I4 as the difference between the reference voltage Vref and the comparison voltage Vcomp becomes larger.

Exemplary embodiments of the present disclosure have been described above. The power amplifier circuit 10 according to the first embodiment includes the transistor 101 having the base to which the bias current IB1 is supplied, amplifying the input signal RFin, and outputting the current I1, the transistor 102 having the emitter connected to the base of the transistor 101 and supplying the bias current IB1 from the emitter to the base of the transistor 101, and the transistor 1031 connected to the base of the transistor 102. The power amplifier circuit 10 includes the comparison voltage generation circuit 103 generating the comparison voltage Vcomp based on the current I2 flowing through the transistor 1031, and the comparison circuit 104 connected to the base of the transistor 102, to which the comparison voltage Vcomp and the reference voltage Vref are supplied, and decreasing the current I3a supplied to the base of the transistor 102 as the current I2 increases based on the comparison voltage Vcomp and the reference voltage Vref.

When the input to the transistor 101 increases and the current I1 increases, the transistor 101 generates heat. The heat generated by the transistor 101 is transmitted to the transistor 1031, and the operating point of the transistor 1031 changes. For example, when the temperature of the transistor 1031 increases, the operating point of the transistor 1031 changes to increase the current I2 or to decrease the comparison voltage Vcomp. The comparison circuit 104 decreases the current I3a supplied to the base of the transistor 102 based on the above change detected by the comparison voltage generation circuit 103. Thus, the bias current IB1 supplied from the transistor 102 to the transistor 101 decreases. Therefore, an increase in the current I1 flowing through the transistor 101 can be suppressed, and the breakdown of the transistor 101 can be suppressed.

In the power amplifier circuit 10, the comparison circuit 104 may decrease the current I3a by generating the current I4 based on a differential voltage that is a difference between the comparison voltage Vcomp and the reference voltage Vref and removing the current I4 from the current I3a. Further, in the power amplifier circuit 10, the comparison voltage generation circuit 103 may decrease the comparison voltage along with the temperature increase of the transistor 101. According to these aspects as well, an increase in the current I1 flowing through the transistor 101 can be suppressed, and the breakdown of the transistor 101 can be suppressed.

The power amplifier circuit 20 according to the second embodiment includes the transistor 101 having the base to which the bias current IB1 is supplied, amplifying the output signal RF1 corresponding to the input signal RFin and outputting the current I1, the transistor 102 having the emitter connected to the base of the transistor 101 and supplying the bias current IB1 from the emitter to the base of the transistor 101, and the transistor 1031 connected to the base of the transistor 102. The power amplifier circuit includes the comparison voltage generation circuit 103 that generates the comparison voltage Vcomp based on the current I2 flowing through the transistor 1031.

The power amplifier circuit 20 includes the transistor 201 having the base to which the bias current IB2 is supplied and the collector connected to the base of the transistor 101 and configured to amplify the input signal RFin and to output the signal RF1, and the transistor 202 having the emitter connected to the base of the transistor 201 and configured to supply the bias current IB2 from the emitter to the base of the transistor 201.

The power amplifier circuit 20 includes the comparison circuit 104A which is connected to the base of the transistor 102 and the base of the transistor 202, to which the comparison voltage Vcomp and the reference voltage Vref are supplied, and which decreases the current I3b supplied to the base of the transistor 202 based on the comparison voltage Vcomp and the reference voltage Vref.

In the power amplifier circuit 20, in a case where the input to the transistor 101 increases and the current I1 increases, the transistor 101 generates heat. The heat generated by the transistor 101 is transmitted to the transistor 1031, and the operating point of the transistor 1031 changes. For example, when the temperature of the transistor 1031 increases, the operating point of the transistor 1031 changes to increase the current I2 or to decrease the comparison voltage Vcomp. The comparison circuit 104A decreases the current I3b supplied to the base of the transistor 202 based on the above change detected by the comparison voltage generation circuit 103. Due to this, the bias current IB2 supplied from the transistor 202 to the transistor 201 decreases. Thus, the power of the signal RF1 outputted from the transistor 201 is decreased. Therefore, the input power of the transistor 101 is suppressed and an increase in the current I1 flowing through the transistor 101 is suppressed, so that the breakdown of the transistor 101 can be suppressed.

In addition, in the power amplifier circuit 20, the comparison circuit 104A may decrease the current I3b by generating the current I4 based on a differential voltage which is a difference between the comparison voltage Vcomp and the reference voltage Vref and removing the current I4 from the current I3b. Further, in the power amplifier circuit 20, the comparison voltage generation circuit 103 may decrease the comparison voltage along with the temperature increase of the transistor 101. According to these aspects as well, an increase in the current I1 flowing through the transistor 101 can be suppressed, and the breakdown of the transistor 101 can be suppressed.

Note that, each embodiment described above is intended to facilitate the understanding of the present disclosure, and are not intended to be limited to the interpretation of the present disclosure. The present disclosure may be modified or improved without departing from the gist thereof, and equivalents thereof are also included in the present disclosure. In other words, those skilled in the art may make appropriate design changes to each embodiment and still fall within the scope of the present disclosure as long as they include the features of the present disclosure. For example, each element included in each embodiment and the arrangement, material, condition, shape, size, and the like thereof are not limited to those exemplified and can be appropriately changed. Further, each embodiment is an exemplification, and it is needless to say that partial replacement or combination of configurations illustrated in different embodiments is possible, and these are also included in the scope of the present disclosure as long as the features of the present disclosure are included.

<1>

A power amplifier circuit, comprising: a first transistor having a base or gate to which a bias current or voltage is supplied, and configured to amplify an input signal and to output a first current; a second transistor having an emitter or a source connected to the base or gate of the first transistor, and configured to supply the bias current or the voltage from the emitter or source to the base or gate of the first transistor; a comparison voltage generation circuit including a third transistor connected to a base or gate of the second transistor, and configured to generate a comparison voltage based on a second current flowing through the third transistor; and a comparison circuit connected to the base or gate of the second transistor, supplied with the comparison voltage and a reference voltage, and configured to decrease a third current supplied to the base or gate of the second transistor as the second current increases based on the comparison voltage and the reference voltage.

<2>

The power amplifier circuit according to <1>, further comprising: a bias source connected to the base or gate of the second transistor and configured to generate the third current, wherein the comparison circuit generates a fourth current based on a differential voltage that is a difference between the comparison voltage and the reference voltage, and decreases the third current by removing the fourth current from the third current.

<3>

The power amplifier circuit according to <1> or <2>, wherein the comparison voltage generation circuit decreases the comparison voltage along with a temperature increase of the first transistor.

<4>

The power amplifier circuit according to any one of <1> to <3>, wherein the comparison voltage generation circuit further includes a fourth transistor having a collector or drain connected to the base or gate of the second transistor and an emitter or a source connected to a collector or drain of the third transistor, and a resistance element provided between the collector or drain of the fourth transistor and the comparison circuit.

<5>

The power amplifier circuit according to <4>, wherein the resistance element is a first resistance element, and the comparison voltage generation circuit further includes a fifth transistor having a base or gate connected to a base or gate of the third transistor and a collector or drain connected to the emitter or source of the second transistor, and a second resistance element provided between the collector or drain and the base or gate of the fifth transistor.

<6>

The power amplifier circuit according to any one of <1> to <3>, wherein the comparison voltage generation circuit further includes a capacitance element provided between a collector or drain and a base or gate of the third transistor.

<7>

The power amplifier circuit according to any one of <1> to <6>, further comprising: a bias control circuit configured to supply a bias control signal to the second transistor.

<8>

The power amplifier circuit according to any one of <1> to <7>, wherein the comparison circuit includes a sixth transistor having a base or gate to which the reference voltage is supplied, and a seventh transistor having a collector or drain through which the fourth current flows.

<9>

A power amplifier circuit, comprising: a first transistor having a base or gate to which a first bias current or voltage is supplied, and configured to amplify a first signal and to output a first current; a second transistor having an emitter or a source connected to the base or gate of the first transistor, and configured to supply the first bias current or voltage from the emitter or source to the base or gate of the first transistor; a comparison voltage generation circuit including a third transistor connected to a base or gate of the second transistor, and configured to generate a comparison voltage based on a second current flowing through the third transistor; a fourth transistor having a base or gate to which a second bias current or voltage is supplied and a collector or drain connected to the base or gate of the first transistor, and configured to amplify an input signal and to output the first signal; a fifth transistor having an emitter or a source connected to the base or gate of the fourth transistor, and configured to supply the second bias current or voltage from the emitter or source to the base or gate of the fourth transistor; and a comparison circuit connected to the base or gate of the second transistor and the base or gate of the fifth transistor, supplied with the comparison voltage and a reference voltage, and configured to decrease a third current supplied to the base or gate of the fifth transistor based on the comparison voltage and the reference voltage.

<10>

The power amplifier circuit according to <9>, further comprising: a bias source connected to the base or gate of the fifth transistor and configured to generate the third current, wherein the comparison circuit generates a fourth current based on a differential voltage that is a difference between the comparison voltage and the reference voltage, and decreases the third current by removing the fourth current from the third current.

<11>

The power amplifier circuit according to <9> or <10>, wherein the comparison voltage generation circuit decreases the comparison voltage along with a temperature increase of the first transistor.

<12>

The power amplifier circuit according to any one of <9> to <11>, wherein the comparison voltage generation circuit further includes a sixth transistor having a collector or drain connected to the base or gate of the second transistor and an emitter or a source connected to a collector or drain of the third transistor, and a resistance element provided between the collector or drain of the sixth transistor and the comparison circuit.

<13>

The power amplifier circuit according to <12>, wherein the resistance element is a first resistance element, and the comparison voltage generation circuit further includes a seventh transistor having a base or gate connected to a base or gate of the third transistor and a collector or drain connected to the emitter or source of the second transistor, and a second resistance element provided between the collector or drain and the base or gate of the seventh transistor.

<14>

The power amplifier circuit according to any one of <9> to <11>, wherein the comparison voltage generation circuit further includes a capacitance element provided between a collector or drain and a base or gate of the third transistor.

<15>

The power amplifier circuit according to any one of <9> to <14>, further comprising: a bias control circuit configured to supply a bias control signal to the second transistor.

<16>

The power amplifier circuit according to any one of <9> to <15>, wherein the comparison circuit includes an eighth transistor having a base or gate to which the reference voltage is supplied, and a ninth transistor having a collector or drain through which the fourth current flows.

What is claimed is:

1. A power amplifier circuit, comprising:
a first transistor having a base or a gate to which a bias current or a bias voltage is supplied, and being configured to amplify an input signal and to output a first current;
a second transistor having an emitter or a source connected to the base or the gate of the first transistor, and being configured to supply the bias current or the bias voltage from the emitter or the source to the base or the gate of the first transistor;
a comparison voltage generation circuit comprising a third transistor connected to a base or a gate of the second transistor, and being configured to generate a comparison voltage based on a second current flowing through the third transistor; and
a comparison circuit connected to the base or the gate of the second transistor, being supplied with the comparison voltage and a reference voltage, and being configured to decrease a third current supplied to the base or the gate of the second transistor as the second current increases, based on the comparison voltage and the reference voltage.

2. The power amplifier circuit according to claim 1, further comprising:
a bias source connected to the base or the gate of the second transistor and being configured to generate the third current,
wherein the comparison circuit is configured to generate a fourth current based on a differential voltage that is a difference between the comparison voltage and the reference voltage, and is configured to decrease the third current by removing the fourth current from the third current.

3. The power amplifier circuit according to claim 1, wherein the comparison voltage generation circuit is configured to decrease the comparison voltage along with a temperature increase of the first transistor.

4. The power amplifier circuit according to claim 1, wherein the comparison voltage generation circuit further comprises:
a fourth transistor having a collector or a drain connected to the base or the gate of the second transistor and an emitter or a source connected to a collector or a drain of the third transistor, and
a first resistance element between the collector or the drain of the fourth transistor, and the comparison circuit.

5. The power amplifier circuit according to claim 4, wherein the comparison voltage generation circuit further comprises:
a fifth transistor having a base or a gate connected to a base or a gate of the third transistor, and a collector or a drain connected to the emitter or the source of the second transistor, and
a second resistance element between the collector or the drain of the fifth transistor, and the base or the gate of the fifth transistor.

6. The power amplifier circuit according to claim 1, wherein the comparison voltage generation circuit further comprises a capacitance element between a collector or a drain of the third transistor, and a base or a gate of the third transistor.

7. The power amplifier circuit according to claim 1, further comprising:
a bias control circuit configured to supply a bias control signal to the second transistor.

8. The power amplifier circuit according to claim 2, wherein the comparison circuit comprises:
a sixth transistor having a base or a gate to which the reference voltage is supplied, and
a seventh transistor having a collector or a drain through which the fourth current flows.

9. A power amplifier circuit, comprising:
a first transistor having a base or a gate to which a first bias current or a first bias voltage is supplied, and being configured to amplify a first signal and to output a first current;
a second transistor having an emitter or a source connected to the base or the gate of the first transistor, and being configured to supply the first bias current or the first bias voltage from the emitter or the source to the base or the gate of the first transistor;
a comparison voltage generation circuit comprising a third transistor connected to a base or a gate of the second transistor, and being configured to generate a comparison voltage based on a second current flowing through the third transistor;
a fourth transistor having a base or a gate to which a second bias current or a second bias voltage is supplied, and a collector or a drain connected to the base or the gate of the first transistor, and being configured to amplify an input signal and to output the first signal;
a fifth transistor having an emitter or a source connected to the base or the gate of the fourth transistor, and being configured to supply the second bias current or the second bias voltage from the emitter or the source to the base or the gate of the fourth transistor; and
a comparison circuit connected to the base or the gate of the second transistor and the base or gate of the fifth transistor, being supplied with the comparison voltage and a reference voltage, and being configured to decrease a third current supplied to the base or the gate of the fifth transistor based on the comparison voltage and the reference voltage.

10. The power amplifier circuit according to claim 9, further comprising:
a bias source connected to the base or the gate of the fifth transistor and configured to generate the third current,
wherein the comparison circuit is configured to generate a fourth current based on a differential voltage that is a difference between the comparison voltage and the reference voltage, and is configured to decrease the third current by removing the fourth current from the third current.

11. The power amplifier circuit according to claim 9, wherein the comparison voltage generation circuit is configured to decrease the comparison voltage with a temperature increase of the first transistor.

12. The power amplifier circuit according to claim 9, wherein the comparison voltage generation circuit further comprises:
a sixth transistor having a collector or a drain connected to the base or the gate of the second transistor, and an emitter or a source connected to a collector or a drain of the third transistor, and
a first resistance element between the collector or the drain of the sixth transistor, and the comparison circuit.

13. The power amplifier circuit according to claim 12, wherein the comparison voltage generation circuit further comprises:
a seventh transistor having a base or a gate connected to a base or a gate of the third transistor, and a collector or a drain connected to the emitter or the source of the second transistor, and
a second resistance element between the collector or the drain of the seventh transistor, and the base or gate of the seventh transistor.

14. The power amplifier circuit according to claim 9, wherein the comparison voltage generation circuit further comprises a capacitance element between a collector or a drain of the third transistor, and a base or gate of the third transistor.

15. The power amplifier circuit according to claim 9, further comprising:
a bias control circuit configured to supply a bias control signal to the second transistor.

16. The power amplifier circuit according to claim 10, wherein the comparison circuit comprises:
an eighth transistor having a base or a gate to which the reference voltage is supplied, and
a ninth transistor having a collector or a drain through which the fourth current flows.
